(19) United States
(12) Patent Application Publication
(10) Pub. No.: US 2014/0230883 A1
(43) Pub. Date: Aug. 21, 2014

(54) CONCENTRATOR PHOTOVOLTAIC MODULE, CONCENTRATOR PHOTOVOLTAIC PANEL, AND FLEXIBLE PRINTED CIRCUIT FOR CONCENTRATOR PHOTOVOLTAIC MODULE

(71) Applicant: SUMITOMO ELECTRIC INDUSTRIES, LTD., Osaka-shi, Osaka (JP)

(72) Inventors: Takashi Iwasaki, Osaka-shi (JP); Kazumasa Toya, Osaka-shi (JP); Kazuhiro Jingoro, Kouga-shi (JP)

(21) Appl. No.: 14/348,870

(22) PCT Filed: Sep. 25, 2012
(86) PCT No.: PCT/JP2012/074524

§ 371 Date: Mar. 31, 2014

(30) Foreign Application Priority Data
Oct. 3, 2011 (JP) 2011-218863

(51) Int. Cl. H01L 31/048; H01L 31/052

(52) U.S. Cl. CPC H01L 31/0485; H01L 31/0524
USPC 136/246

(57) ABSTRACT

As a structure of a concentrator photovoltaic module, a ribbon-shaped flexible printed circuit is arranged along a bottom surface of a vessel-shaped housing. The flexible printed circuit includes a solar cell on a flexible substrate having flexibility, and furthermore, can also include a concentrating portion (a secondary concentrating portion) for concentrating incident sunlight onto the solar cell. Moreover, a primary concentrating portion having a Fresnel lens is attached to the housing side.

### TECHNICAL FIELD

The present invention relates to a concentrator photovoltaic (CPV) for concentrating sunlight on a solar cell, thereby generating power.

### BACKGROUND ART

The concentrator photovoltaic is based on a structure in which a solar cell formed by a small-sized compound semiconductor having a high power generation efficiency is set to be a solar cell and sunlight concentrated by a lens is incident thereon. A concentrator photovoltaic panel having a plurality of basic structures is caused to carry out a tracking operation so as to be always turned toward the sun so that desirable generated power can be obtained. More specifically, for example, a plurality of insulating substrates such as ceramic having a wiring on which a single solar cell is mounted is disposed in a concentrating position to collect generated power on each of the insulating substrates by an electric wire (for example, see Non-Patent Literature 1).

### CITATION LIST

### Non-Patent Literature

Non-Patent Literature 1: “Failure Modes of CPV Modules and How to Test for Them”, [online], Feb. 19, 2010, Emcore Corporation, [Retrieved on Sep. 29, 2011], Internet <URL: http://www1.eere.energy.gov/solar/pdfs/pvrw2010_aeby.pdf#search='emcore Point focus Fresnel Lens HCPV System'>

### SUMMARY OF INVENTION

### Technical Problem

However, the conventional concentrator photovoltaic panel described above requires a large number of insulating substrates such as ceramic. When the large number of insulating substrates is to be arranged and connected through an electric wire respectively, the number of manufacturing steps is increased so that a long time is taken. As a result, a manufacturing cost is increased so that a product having a practically proper price cannot be obtained. If a large substrate is fabricated, the number of the manufacturing steps is decreased. However, the photovoltaic panel originally requires a large area. For this reason, the substrate is to be enlarged considerably. In respect of a manufacturing technique, however, it is hard to fabricate the large substrate.

As described above, a long time is taken for attaching a large number of small substrates and mutually connecting them, while it is hard to fabricate a large substrate in respect of the manufacturing technique.

In consideration of the problems of the related art, it is an object of the present invention to easily manufacture and attach a substrate for a concentrator photovoltaic.

### Solution to Problem

(1) The present invention provides a concentrator photovoltaic module including a vessel-shaped housing having a bottom surface, a flexible printed circuit provided in contact with the bottom surface, and a primary concentrating portion attached to the housing and formed by arranging a plurality of lens elements for concentrating sunlight, the flexible printed circuit including a flexible substrate having an insulating base material with an insulating property and a conductive pattern and having flexibility, and a plurality of solar cells provided corresponding to the respective lens elements on the flexible substrate and connected electrically to each other through the pattern.

In the concentrator photovoltaic module having the structure described above, the solar cell is provided on a flexible substrate having a proper dimension which can easily be fabricated. Consequently, it is possible to easily manufacture a flexible printed circuit having a function of a concentrator photovoltaic. Since the flexible printed circuit can be spread in a desirable extent (area), moreover, it is suitable for a large-sized concentrator photovoltaic module.

Furthermore, the flexible printed circuit is thin and has a light weight. Therefore, the whole concentrator photovoltaic module also has a light weight and can easily be handled. In addition, the flexible printed circuit is thin and has flexibility. Consequently, it is easy to carry out an attachment in close contact with the bottom surface of the housing. Because of the adhesion and thinness, furthermore, the heat of the solar cell or other flexible printed circuits can reliably be dissipated to the housing.

(2) In the concentrator photovoltaic module of (1), moreover, the flexible printed circuit is constituted by arranging, on the bottom surface, the flexible substrate taking a shape of a ribbon, for example.

In this case, it is possible to spread the flexible printed circuit in a desirable extent while carrying out a control to minimize an area thereof.

(3) In the concentrator photovoltaic module of (1) or (2), furthermore, the flexible printed circuit may include a plurality of circuits for power generation having the solar cells capable of generating a predetermined voltage and a circuit for connection for electrically connecting the circuits for power generation to each other.

In this case, it is possible to easily connect the circuits for power generation mutually by the circuit for connection.

(4) In the concentrator photovoltaic module of (3), moreover, the circuit for power generation may take a shape extended linearly over the bottom surface or a shape extended linearly from a center to an end in the bottom surface and returned to the center.

In this case, a length of the circuit for power generation can be ensured sufficiently. Therefore, it is possible to easily arrange a necessary number of solar cells, thereby connecting them to each other in series in order to obtain a desirable voltage.

(5) In the concentrator photovoltaic module of any one of (1) to (4), furthermore, it is preferable that a thickness of the insulating base material should be 10 to 100 μm.

In this case, withstand voltage performance and a heat dissipating property can be compatible with each other. In other words, if the thickness is smaller than 10 μm, the withstand voltage performance is insufficient. If the thickness exceeds 100 μm, a heat dissipating property for the housing is deteriorated.

(6) In the concentrator photovoltaic module of any one of (1) to (5), moreover, a reinforcing plate for reinforcing the insulating base material may be provided on a lower surface of the insulating base material at an opposite side to a surface for attaching the solar cell thereto.

In this case, by the reinforcement of the reinforcing plate, it is possible to ensure a slight hardness of the flexible printed circuit in such a manner that flexibility is not lost. Thus, it is possible to easily handle in manufacturing, and furthermore, to obtain a deformation preventing effect. Moreover, the reinforcing plate is formed of aluminum, for example. Consequently, it is possible to enhance a thermal conductivity (a heat dissipating property) to the bottom surface of the housing.

(7) In the concentrator photovoltaic module of any one of (1) to (6), furthermore, portions to be fitted in each other may be formed for positioning over the bottom surface and the flexible substrate.

In this case, positioning can be carried out easily and reliably in the attachment of the flexible printed circuit to the bottom surface of the housing.

(8) In the concentrator photovoltaic module of (3), moreover, it is also possible to provide the circuit for connection on an inside surface of the housing.

In other words, the circuit for connection which does not have the solar cell can also be attached to the inside surface which is exposed to light with difficulty. Consequently, the inside surface of the housing can also be utilized effectively.

(9) In the concentrator photovoltaic module of any one of (1) to (8), furthermore, it is preferable that the housing should be formed of metal.

In this case, the housing has a high thermal conductivity. Therefore, the dissipating property from the flexible printed circuit is particularly excellent.

(10) In the concentrator photovoltaic module of (9), moreover, it is preferable that the housing should be formed of aluminum.

In this case, the housing has a light weight and the whole concentrator photovoltaic module also has a light weight.

(11) In the concentrator photovoltaic module of any one of (1) to (8), furthermore, the housing may be formed by a resin.

In this case, the housing particularly has a light weight and the whole concentrator photovoltaic module also has a light weight especially. The resin also has a thermal conductivity. Therefore, a constant heat dissipating property can be obtained. In particular, a resin to which an insulating filler having a high thermal conductivity (for example, alumina, silica, silicon carbide, magnesium oxide or the like) is added is excellent in a thermal conductivity and has a dissipating property enhanced, which is suitable.

(12) In the concentrator photovoltaic module of any one of (1) to (11), moreover, there may be included a secondary concentrating portion provided on the flexible substrate for collecting, onto the solar cell, sunlight incident from each of the lens elements.

In this case, the secondary concentrating portion can also be mounted to be included in the flexible printed circuit.

(13) Furthermore, it is possible to constitute a concentrator photovoltaic panel by collecting a plurality of concentrator photovoltaic modules according to any one of (1) to (12).

In this case, it is possible to ensure a desirable output (a rated output) for the power generation panel.

(14) On the other hand, a flexible printed circuit for a concentrator photovoltaic module according to the present invention includes a flexible substrate having an insulating base material with an insulating property and a conductive pattern and having flexibility, and a plurality of solar cells arranged on the flexible substrate and connected electrically to each other through the pattern.

In the flexible printed circuit for a concentrator photovoltaic module having the structure described above, the solar cell and the concentrating portion are provided on the flexible substrate having a proper dimension which can easily be fabricated. Consequently, it is possible to easily manufacture the flexible printed circuit provided with the function of the concentrator photovoltaic. Since the flexible printed circuit can be spread into a desirable extent (area), moreover, it is suitable for a substrate for a large-sized concentrator photovoltaic module.

Polyimide having an excellent heat resistance is suitable for the insulating base material of the flexible substrate, for example.

(15) In the flexible printed circuit for a concentrator photovoltaic module of (14), moreover, there may be included a concentrating portion provided on the flexible substrate for concentrating incident sunlight onto the solar cell.

In this case, the concentrating portion can also be mounted to be included in the flexible printed circuit.

(16) In the concentrator photovoltaic module of any one of (1) to (12), wherein the insulating base of the flexible substrate is formed of polyimide.

In this case, the insulating base has an excellent heat resistance.

### Advantageous Effects of Invention

According to the concentrator photovoltaic module, the concentrator photovoltaic panel or the flexible printed circuit for the concentrator photovoltaic module in accordance with the present invention, it is possible to easily manufacture and attach a substrate for a concentrator photovoltaic.

### BRIEF DESCRIPTION OF DRAWINGS

FIG. 1 is a perspective view showing a concentrator photovoltaic according to an embodiment of the present invention.

FIG. 2 is a perspective view showing an enlarged concentrator photovoltaic module (a part of which is taken away).

FIG. 3 is an enlarged view showing a III portion in FIG. 2.

FIG. 4 is a view showing an outline of a partial section of the concentrator photovoltaic module in a portion in which a solar cell is provided.

FIG. 5 is a view showing an example of an arrangement of a flexible printed circuit spread on a bottom surface of a housing as seen on a plane.

FIG. 6 is an enlarged view showing a circuit for power generation.

FIG. 7 is an enlarged view showing a VII portion in FIG. 6.

FIG. 8 is a plan view showing another example of the arrangement of the flexible printed circuit.

FIG. 9 is a plan view showing an example in which a circuit for connection is provided on an inside surface of a housing.

FIG. 10 is a plan view showing another example in which the circuit for connection is provided on the inside surface of the housing.

### DESCRIPTION OF EMBODIMENTS

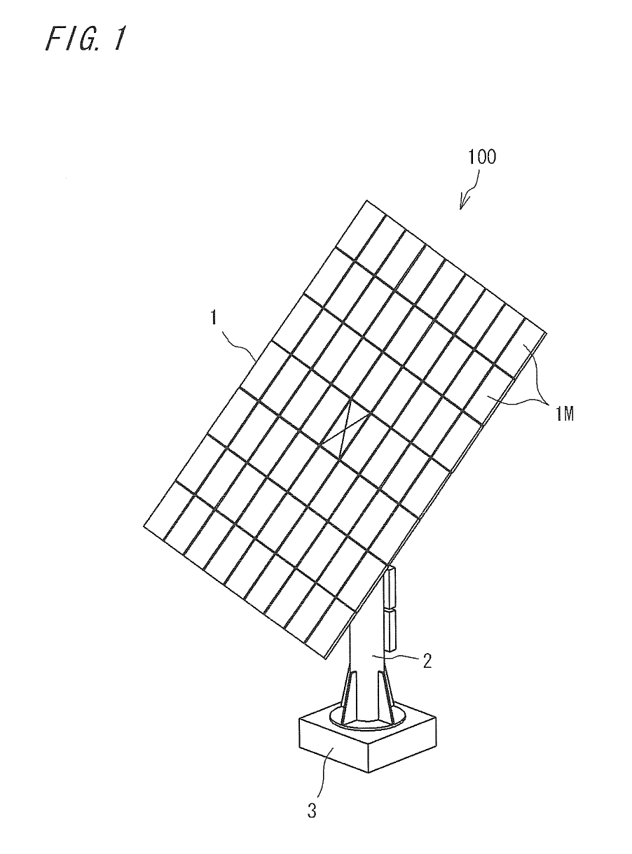

FIG. 1 is a perspective view showing a concentrator photovoltaic according to an embodiment of the present invention. In FIG. 1, a concentrator photovoltaic 100 includes a concentrator photovoltaic panel 1, a strut 2 for supporting the same at a center on a back surface, and a base 3 for attaching the strut 2 thereto. The concentrator photovoltaic panel 1 is obtained by collecting 62 (a length of 7 by a breadth of 9−1) concentrator photovoltaic modules 1M vertically and transversely except for a central part for connection to the strut 2, for example. The single concentrator photovoltaic module 1M has a rated output of approximately 100 W, for example, and the whole concentrator photovoltaic panel 1 has a rated output of approximately 6 kW. The base 3 can be rotated with the strut 2 set to be an axis through a rotating mechanism which is not shown, and can cause the concentrator photovoltaic panel 1 to carry out tracking so as to be always turned in a direction of the sun.

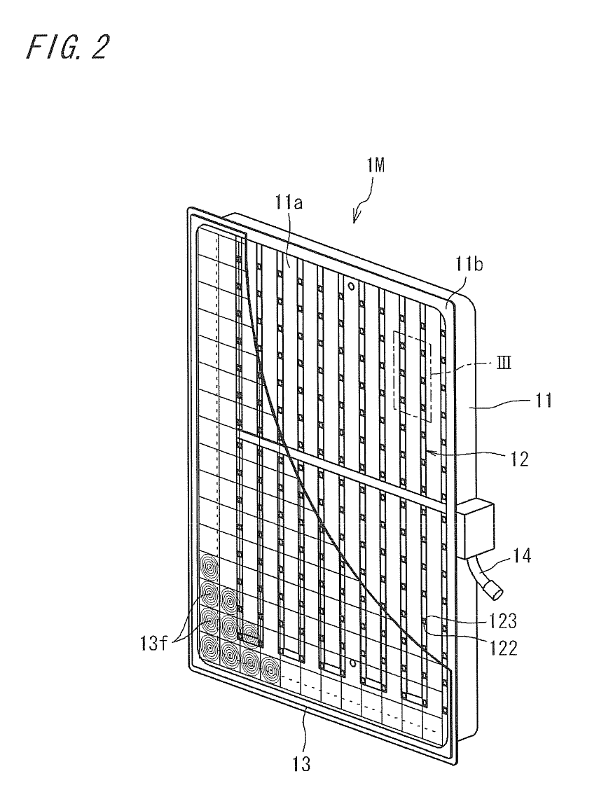

FIG. 2 is a perspective view (a part of which is taken away) showing the concentrator photovoltaic module (hereinafter referred to as a module) 1M which is enlarged. In FIG. 2, the module 1M includes, as main components, a housing 11 taking a shape of a vessel (a vat) and having a bottom surface 11a, a flexible printed circuit 12 provided in contact with the bottom surface 11a, and a primary concentrating portion 13 attached like a cover to a flange portion 11b of the housing 11.

The primary concentrating portion 13 is a Fresnel lens array and is formed by arranging, in a matrix, a plurality of (for example, a length of 16 by a breadth of 12, 192) Fresnel lenses 13f to be lens elements for concentrating sunlight. The primary concentrating portion 13 can be obtained by forming a silicone resin film on a back surface (an inside) with a glass plate set to be a base material, for example. The Fresnel lens is formed on the resin film. An external surface of the housing 11 is provided with a connector 14 for fetching an output of the module 1M.

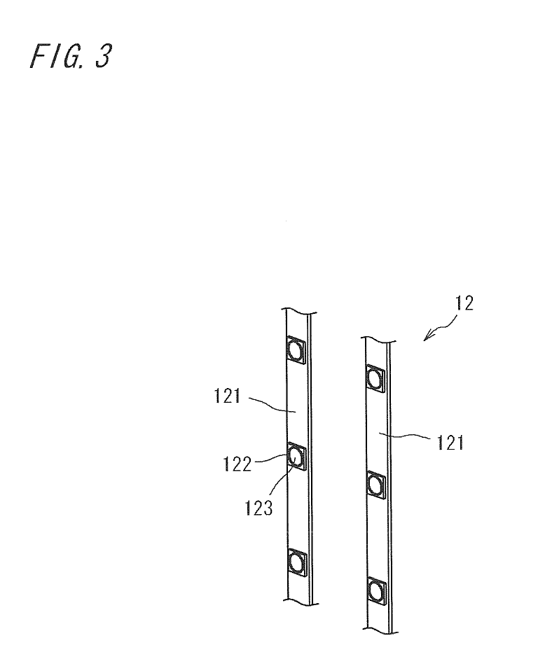

FIG. 3 is an enlarged view showing a III portion in FIG. 2. In FIG. 3, the flexible printed circuit 12 includes a ribbon-shaped flexible substrate 121, a solar cell 122 provided thereon, and a secondary concentrating portion 123 provided to cover the solar cell 122. The same number of sets of the solar cells 122 and the secondary concentrating portions 123 are provided in corresponding positions to the respective Fresnel lenses 13f of the primary concentrating portion 13. The secondary concentrating portion 123 collects the sunlight incident from each of the Fresnel lenses 13f onto the solar cell 122. The secondary concentrating portion 123 is a lens, for example. The secondary concentrating portion 123 may be a reflecting mirror for guiding light downward while reflecting the light irregularly.

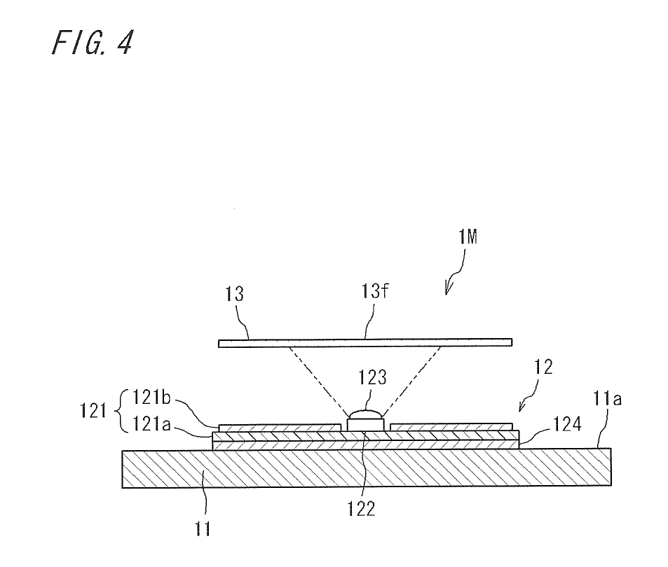

FIG. 4 is a view showing an outline of a partial section of the module 1M in a portion in which the solar cell 122 is provided. In FIG. 4, the solar cell 122 and the secondary concentrating portion 123 are positioned just under the Fresnel lens 13f of the primary concentrating portion 13 in such a manner that mutual optical axes are aligned with each other. The flexible printed circuit 12 is constituted by a flexible substrate 121, and electronic components, optical components and the like mounted thereon (herein, the solar cell 122 and the secondary concentrating portion 123).

The flexible substrate 121 is constituted by an insulating base material 121a formed of polyimide and having an excellent heat resistance, and a conductive pattern 121b formed by a copper foil, for example. The pattern 121b is insulated from the housing 11 through the insulating base material 121a. It is preferable that the insulating base material 121a should have a thickness of 10 to 100 μm. Consequently, withstand voltage performance and a heat dissipating property can be compatible with each other. In other words, the withstand voltage performance is insufficient if the thickness is smaller than 10 μm. If the thickness exceeds 100 μm, the heat dissipating property for the housing 11 is deteriorated. The pattern 121b has a thickness of approximately 35 μm, for example.

Accordingly, the whole flexible substrate 121 is very thin and has flexibility.

Moreover, a reinforcing plate 124 formed of aluminum is bonded to a lower surface of the insulating base material 121a, for example. The reinforcing plate 124 has a thickness of 0.5 to 1.2 mm, for example. By the reinforcement of the reinforcing plate 124, it is possible to ensure a slight hardness in the flexible printed circuit 12 in such a manner that flexibility is not lost. Thus, it is possible to easily handle in manufacturing, and furthermore, to obtain a deformation preventing effect. By forming the reinforcing plate 124 of aluminum, moreover, it is possible to enhance a thermal conductivity (a heat dissipating property) to the bottom surface 11a of the housing 11. The reinforcing plate 124 is bonded to the bottom surface 11a of the housing 11. The flexible printed circuit 12 wholly has a very light weight even if the reinforcing plate 124 is added.

The reinforcing plate 124 is not an essential structure so that it can also be omitted. In the case in which the reinforcing plate 124 is omitted, the flexible substrate 121 is directly bonded to the bottom surface 11a. In that case, moreover, the housing 11 maintains the deformation preventing and heat dissipating functions of the flexible printed circuit 12.

The housing 11 is formed of metal, and aluminum is suitable, for example. Since the housing 11 is formed of the metal, it has a high thermal conductivity. Accordingly, the heat disspating property from the flexible printed circuit 12 to the housing 11 is particularly excellent.

Moreover, the flexible printed circuit 12 or the like has a very light weight, and furthermore, the housing 11 is formed of the aluminum. Consequently, the whole concentrator photovoltaic module 1M has a light weight. The light weight causes a transportation to be easily carried out. An extent of the “light weight” will be taken as an example. In the case in which a length, a breadth and a depth of the module 1M are 840 mm, 640 mm, and 85 mm respectively, a weight of 8 kg or less can be implemented.

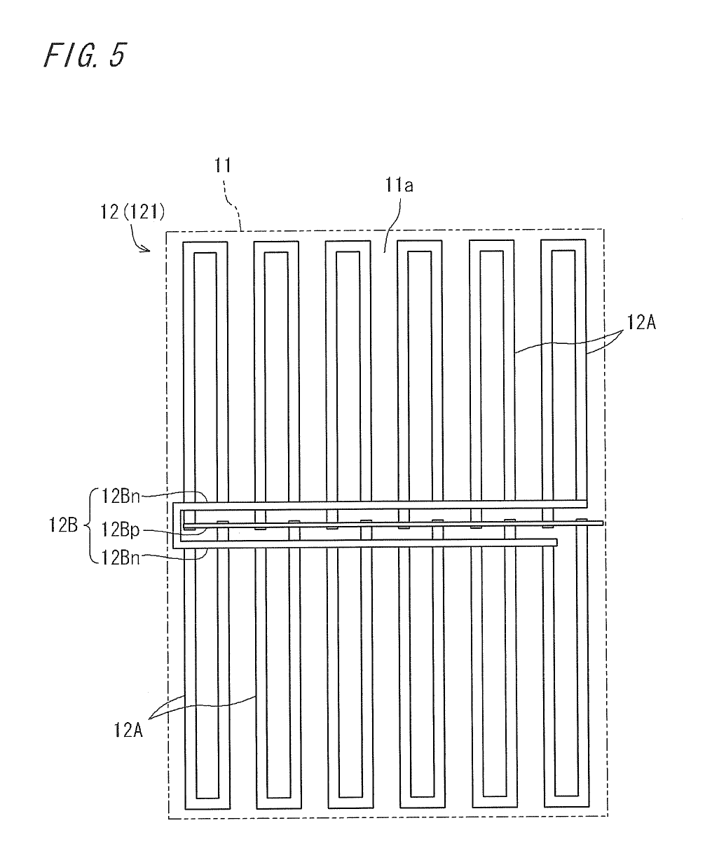

FIG. 5 is a view showing an example of the arrangement of the flexible printed circuit 12 which is provided to spread over the bottom surface 11a of the housing 11 (since the details are omitted, the flexible substrate 121 is substantially illustrated) as seen on a plane. Thus, the flexible printed circuit 12 takes a basic shape (a shape of the flexible substrate 121) of a thin and slender ribbon, and is arranged over the bottom surface 11a vertically and transversely and can be thus spread in a desirable extent (area), which is suitable for the large-sized concentrator photovoltaic module 1M. In other words, the whole flexible printed circuit 12 thus provided is matched with a single substrate or an aggregate of the substrates which has the same size. Because of the shape of the ribbon, moreover, it is possible to spread the flexible printed circuit 12 in a desirable extent while carrying out a control to minimize the area of the flexible printed circuit 12.

The flexible printed circuit 12 shown in FIG. 5 is constituted by 12 sets of circuits 12A for power generation and a circuit 12B for connection, for example. The circuit 12A for power generation is formed to take a U shape. Such a shape may be obtained by coupling linear portions or integrally.

The same number of solar cells is mounted on the circuit 12A for power generation and can generate a predetermined voltage. By causing the circuit 12A for power generation to take such a shape as to be extended from the center toward the end in the bottom surface 11a and returned to the center, thus, it is possible to sufficiently ensure a length of the circuit 12A for power generation. In order to obtain the desirable voltage, therefore, it is possible to easily dispose a necessary number of solar cells, thereby connecting them mutually in series. By providing the circuit 12B for connection on the center to cross the circuit 12A for power generation, moreover, it is possible to easily connect the 12 sets of circuits 12A for power generation mutually.

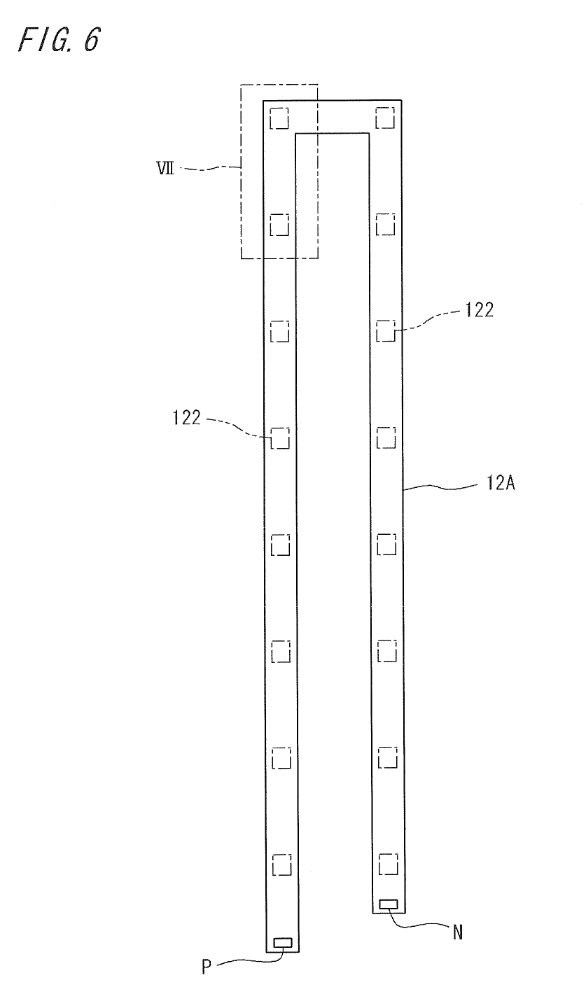

FIG. 6 is an enlarged view showing the circuit 12A for power generation. For example, 16 solar cells 122 are mounted on the circuit 12A for power generation. All of the solar cells 122 mounted on the single circuit 12A for power generation are connected in series to each other. The single solar cell 122 generates a voltage of 2.5 V and 16 series bodies can generate a voltage of 40 V (2.5 V×16). The voltage appears on a positive side electrode P and a negative side electrode N which are provided on two ends of the circuit 12A for power generation.

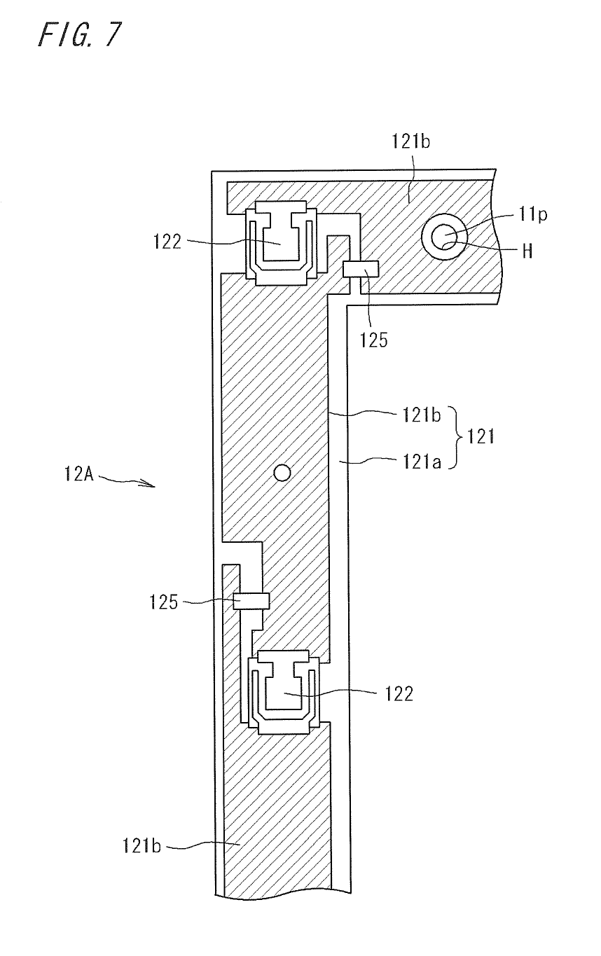

FIG. 7 is an enlarged view showing a VII portion in FIG. 6. In FIG. 7, a pattern 121b shown in a slant line is formed on the insulating base material 121a by etching or the like. The solar cell 122 is inserted in series between the adjacent patterns 121b to each other. Moreover, a diode 125 is provided in parallel with the solar cell 122 to form a bypass of the solar cell 122. The diode 125 is provided to short-circuit the adjacent patterns 121b to each other when the solar cell 122 does not generate power. Consequently, any of the solar cells 122 which does not locally generate power due to a failure or the like can prevent from disturbing the power generation of the whole circuit 12A for power generation. A surface of the flexible substrate 121 excluding the solar cell 122 is coated with an insulating protective film.

Moreover, positioning holes are formed on the insulating base material 121a, and a hole H is shown as one of them in FIG. 7. The pattern 121b is removed circularly around the hole H so as not to reach an edge thereof. By inserting, into the hole H, a cylindrical projection 11p formed on the bottom surface 11a of the housing 11, it is possible to place the circuit 12A for power generation in a predetermined position with respect to the housing 11. The circuit 12B for connection can also be provided with the same positioning structure.

The structure in which the hole H of the insulating base material 121a and the projection 11p on the housing 11 side are fitted in each other is only illustrative and positioning can be carried out easily and reliably in the attachment of the flexible printed circuit 12 to the bottom surface 11a of the housing 11 by the formation of other various fitting portions in each other.

Returning to FIG. 5, referring to the outputs of the 12 sets of circuits 12A for power generation, the positive side electrodes P (FIG. 6) are connected mutually through an electric circuit 12Bp for connection and the negative side electrodes N (FIG. 6) are connected mutually through an electric circuit 12Bn for connection. Consequently, 12 parallel circuits of 40 V are constituted, for example, and the whole single module 1M can supply the 100 W (2.5 A).

According to the structure of the module 1M using the flexible printed circuit 12 as described above, the flexible printed circuit 12 is thin and has a light weight. Consequently, the whole module 1M also has a light weight and can easily be handled. In addition, since the flexible printed circuit 12 is thin and flexible, it can easily be attached in close contact with the bottom surface 11a of the housing 11. Furthermore, the adhesion and thinness can cause the heat of the solar cell 122 or other flexible printed circuits to be reliably dissipated to the housing 11.

Although the housing 11 is formed of the metal in the embodiment, it is not restricted to be formed of the metal but can also be formed by a resin. In this case, the housing 11 particularly has a light weight and the whole concentrator photovoltaic module 1M also has a light weight especially. The resin also has a thermal conductivity. Therefore, a constant heat dissipating property can be obtained. In particular, a resin to which an insulating filler having a high thermal conductivity (for example, alumina, silica, silicon carbide, magnesium oxide or the like) is added is excellent in a thermal conductivity and has a heat dissipating property enhanced, which is suitable. By applying metal coating to a surface of the resin, moreover, it is also possible to enhance the thermal conductivity of the surface to be equivalent to that of the metal.

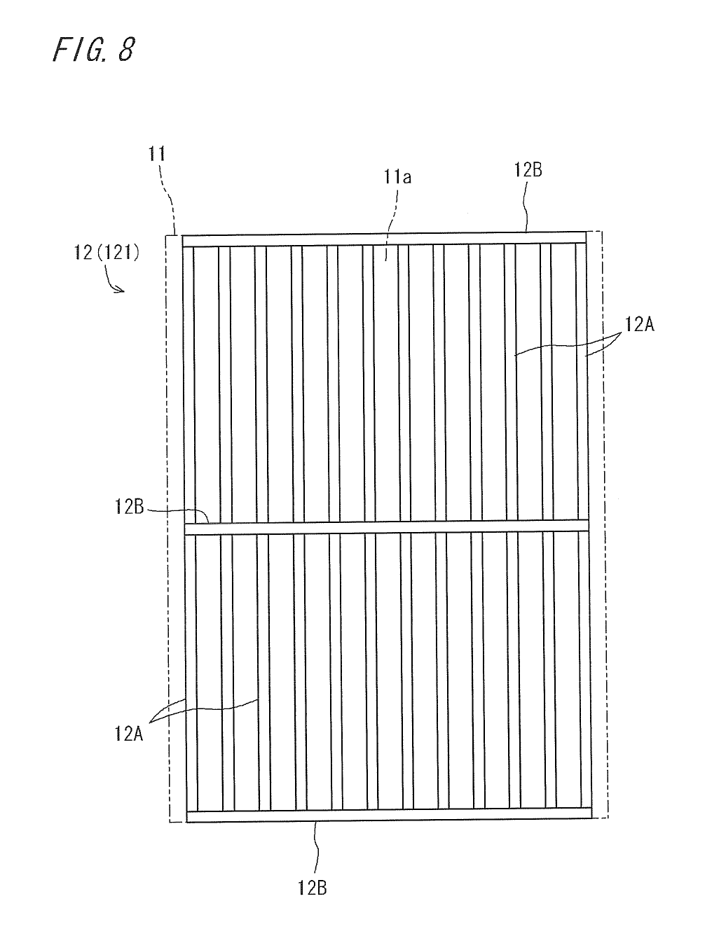

Moreover, the arrangement of the flexible printed circuit shown in FIG. 5 is only illustrative and various changes can be made if the same output is ensured. FIG. 8 is a plan view showing another example of the arrangement of the flexible printed circuit. In this case, the circuit 12A for power generation is set to be simply linear and the circuit 12B for connection is provided on the center and the upper and lower ends. For example, the circuit 12B for connection which is provided on the center is used for the mutual connection of the circuits 12A in the upper and lower stages and the circuits 12B for connection which are provided on the upper and lower ends are used for the positive and negative outputs.

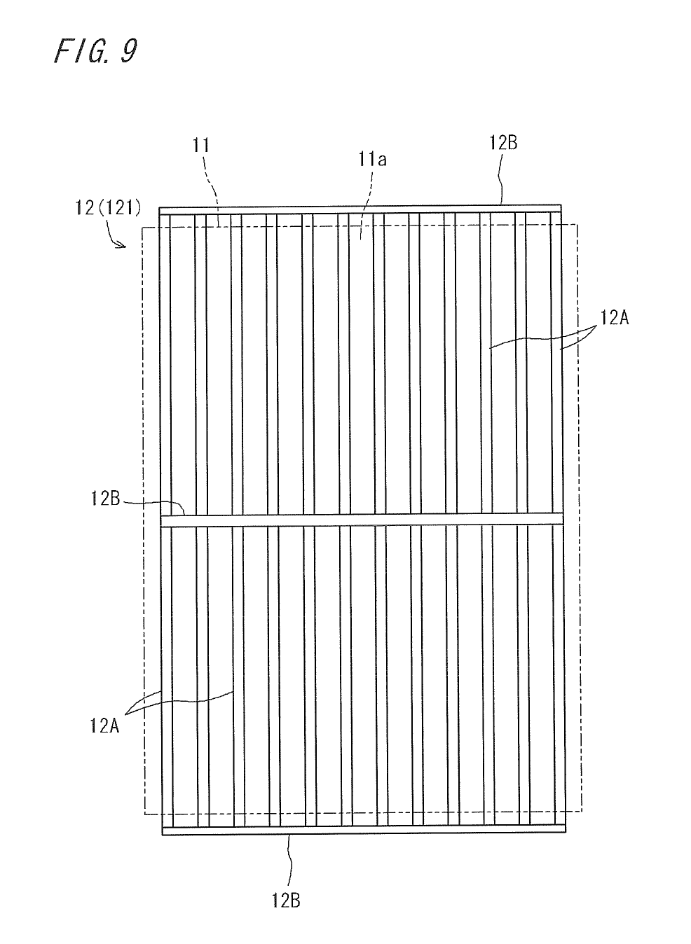

Since the circuit 12B for connection does not need to be exposed to light in the first place, moreover, it may be provided on the inside surface of the housing 11. FIG. 9 is a plan view showing an example in which the circuit 12B for connection is provided on the inside surface of the housing 11. In other words, in this example, the circuits 12B for connection which are provided on the upper and lower ends in FIG. 8 are slightly extended over side surfaces (in upper and lower side surfaces of the drawing). Consequently, it is also possible to practically use the inside surface of the housing 11.

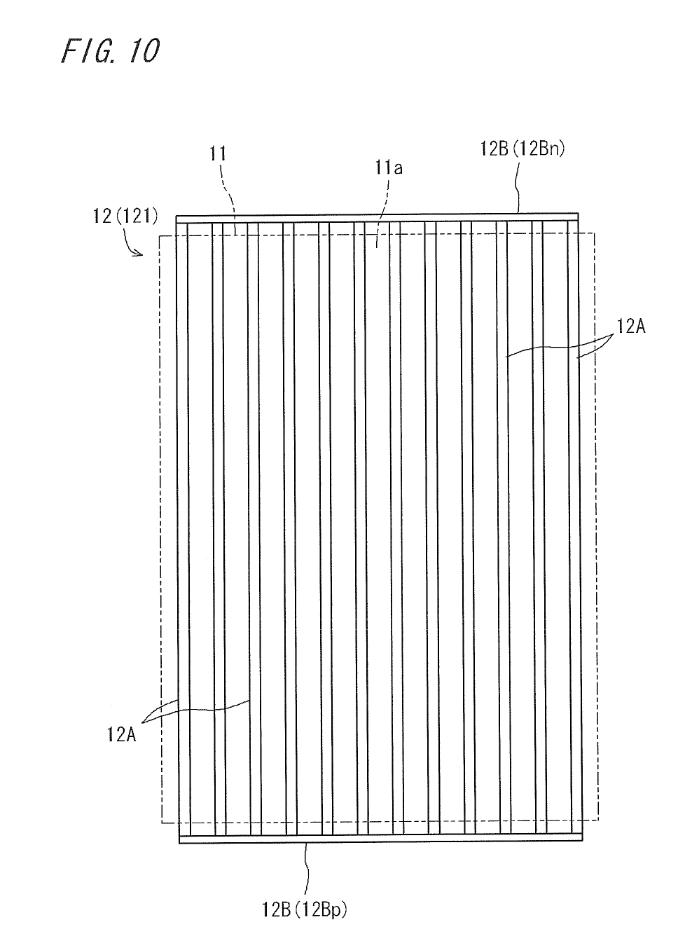

Furthermore, FIG. 10 is a plan view showing another example in which the circuit 12B for connection is provided on the inside surface of the housing 11. In other words, in this structure, the circuit 12B for connection which is provided on the center in FIG. 9 is omitted and the single circuit 12A for power generation is provided in a longitudinal direction. The circuits 12B for connection (12Bp and 12Bn) are provided on the upper and lower side surfaces in FIG. 10, and the positive sides and the negative sides in the circuit 12A for power generation are connected mutually. Consequently, the inside surface of the housing 11 can be used practically and the circuit 12B for connection which is provided on the center can also be omitted.

Although the secondary concentrating portion 123 is mounted on the flexible substrate 121 together with the solar cell 122 in the embodiment, the secondary concentrating portion 123 can also be provided separately from the flexible substrate 121, and furthermore, there is a possibility that the secondary concentrating portion itself might be omitted.

It should be construed that the embodiment disclosed at this time is illustrative in all respects and is not restrictive. The scope of the present invention is indicated by the claims and it is intended that all changes in the claims, equivalent meanings and ranges are included therein.

### REFERENCE SIGNS LIST

1 Concentrating photovoltaic generation panel

1M Concentrating photovoltaic generation module

11 Housing

11a bottom surface

11p Projection

12 Flexible printed wiring board

12A Wring boards for power generation

12B Wiring board for connection

13 Primary concentrating portion

13f Fresnel lens (Lens element)

121 Flexible substrate

121a Insulating base material

121b Pattern

122 Power generation device

123 Secondary concentrating portion

124 Reinforcing plate

H Hole

1. A concentrator photovoltaic module comprising:
a vessel-shaped housing having a bottom surface;
a flexible printed circuit provided in contact with the bottom surface; and
a primary concentrating portion attached to the housing and formed by arranging a plurality of lens elements for concentrating sunlight,
the flexible printed circuit including:
a flexible substrate having an insulating base material with an insulating property and a conductive pattern and having flexibility; and
a plurality of solar cells provided corresponding to the respective lens elements on the flexible substrate and connected electrically to each other through the pattern.

2. The concentrator photovoltaic module according to claim 1, wherein the flexible printed circuit is constituted by arranging, on the bottom surface, the flexible substrate taking a shape of a ribbon.

3. The concentrator photovoltaic module according to claim 1, wherein the flexible printed circuit includes a plurality of circuits for power generation having the solar cells capable of generating a predetermined voltage and a circuit for connection for electrically connecting the circuits for power generation to each other.

4. The concentrator photovoltaic module according to claim 3, wherein the circuit for power generation takes a shape extended linearly over the bottom surface or a shape extended linearly from a center to an end in the bottom surface and returned to the center.

5. The concentrator photovoltaic module according to claim 1, wherein a thickness of the insulating base material is 10 to 100 μm.

6. The concentrator photovoltaic module according to claim 1, wherein a reinforcing plate for reinforcing the insulating base material is provided on a lower surface of the insulating base material at an opposite side to a surface for attaching the solar cell thereto.

7. The concentrator photovoltaic module according to claim 1, wherein portions to be fitted in each other are formed for positioning over the bottom surface and the flexible substrate.

8. The concentrator photovoltaic module according to claim 3, wherein the circuit for connection is provided on an inside surface of the housing.

9. The concentrator photovoltaic module according to claim 1, wherein the housing is formed of metal.

10. The concentrator photovoltaic module according to claim 9, wherein the housing is formed of aluminum.

11. The concentrator photovoltaic module according to claim 1, wherein the housing is formed by a resin.

12. The concentrator photovoltaic module according to claim 1, comprising a secondary concentrating portion provided on the flexible substrate for collecting, onto the solar cell, sunlight incident from each of the lens elements.

13. A concentrator photovoltaic panel formed by collecting a plurality of concentrator photovoltaic modules according to claim 1.

14. A flexible printed circuit for a concentrator photovoltaic module comprising:
a flexible substrate having an insulating base material with an insulating property and a conductive pattern and having flexibility; and
a plurality of solar cells arranged on the flexible substrate and connected electrically to each other through the pattern.

15. The flexible printed circuit for a concentrator photovoltaic module according to claim 14, comprising a concentrating portion provided on the flexible substrate for concentrating incident sunlight onto the solar cell.

16. The concentrator photovoltaic module according to claim 1, wherein the insulating base of the flexible substrate is formed of polyimide.
